(19) United States
(12) Patent Application Publication
(10) Pub. No.: US 2004/0073858 A1
(43) Pub. Date: Apr. 15, 2004

(54) Method and apparatus for isolating faulty semiconductor devices in a graphics system

(76) Inventor: Tyvis C. Cheung, Sunnyvale, CA (US)

Correspondence Address: B Noel Kivlin, MEYERTONS HOOD KIVLIN KOWERT & GOETZEL PC, P O Box 398, Austin, TX, 78767-0398, US

(21) Appl. No.: 10/267,804

(22) Filed: Oct. 9, 2002

(51) Int. Cl. G01R 31/28

(52) U.S. Cl. 714/732

(57) ABSTRACT

A method and an apparatus are provided for isolating faulty semiconductor devices in a multiple stream graphics system. The apparatus includes a buffer adapted to receive a data stream and a convolver comprising at least one signature register, wherein the signature register is adapted to store a plurality of bits. The apparatus further includes a router adapted to route the data stream from the buffer to the convolver and an analyzer adapted to access the signature registers, wherein the analyzer is capable of isolating at least one of a faulty semiconductor device and a faulty interconnect using the plurality of bits stored in the signature register.

### BACKGROUND OF THE INVENTION

1. Field of the Invention

This invention relates generally to computer hardware and, more particularly, to a method and apparatus for isolating faulty semiconductor devices in a graphics system.

2. Description of the Related Art

In modern video graphics systems, streams of digital bits have taken the place of the traditional reel of celluloid film composed of individual still photographs. The laborious task of processing video data may now be done with the assistance of processors in the video graphics systems, which may be capable of working on multiple streams of data from a variety of sources at once. For example, a single video graphics system may receive streams of data from devices such as a digital camera, a graphics rendering device, a computer-assisted design program, and the like. The video graphics system may also provide post-processed video data to a variety of output devices, including video projectors, televisions, monitors, and the like.

Video graphics systems may include tens or hundreds of semiconductor devices designed to perform various functions. Like all complex semiconductor devices, the semiconductor devices in the video graphics system may occasionally have intrinsic defects that cause the video graphics system to operate in an undesirable manner. The semiconductor devices may also become faulty during operation of the video graphics system. Even a single faulty semiconductor device can cause the video graphics system to operate in an incorrect or undesirable manner, so it is desirable to isolate faults to a single failing semiconductor device.

However, the increasing complexity of video graphics systems, and corresponding decreasing size of their semiconductor elements, has made it increasingly difficult to test the video graphics system. Simply observing the screen output of the video graphics system may reveal undesirable operation, but it may not be a sensitive enough test to detect some errors in high resolution video outputs. Nor may observing the screen provide any indication of which semiconductor device may be faulty. External test equipment like logic analyzers, logic probes and/or oscilloscopes may also have limited usefulness as the size of the semiconductor components continues to decrease.

In recent years, signature analysis using signature registers included in the video graphics system has been developed to provide reliable indications of the correct operation of digital systems. However, not all semiconductor devices may be manufactured with signature registers. For example, a video graphics system may include 92 semiconductor devices, but only 64 of the semiconductor devices may contain signature registers. Isolating faulty semiconductor devices that do not contain signature registers by traditional signature analysis techniques may be exceedingly difficult. Consequently, traditional signature analysis may not be an effective way to isolate faulty semiconductor devices in video graphics systems.

### SUMMARY OF THE INVENTION

In one aspect of the present invention, an apparatus is provided for isolating faulty semiconductor devices in a graphics system. The apparatus includes a buffer adapted to receive a data stream. The apparatus further includes a convolver comprising at least one signature register, wherein the signature register is adapted to store a plurality of bits, a router adapted to route the data stream from the buffer to the convolver; and an analyzer adapted to access the signature registers, wherein the analyzer is capable of isolating at least one of a faulty semiconductor device and a faulty interconnect using the plurality of bits stored in the signature registers.

In another aspect of the instant invention, a method is provided for isolating faulty semiconductor devices in a graphics system. The method includes providing a test pattern to a buffer via a data stream, wherein the buffer is coupled to a router and a convolver. The method further includes accessing at least one signature register in the convolver, wherein the signature register is adapted to store a plurality of bits, and detecting at least one of a faulty semiconductor device and a faulty interconnect using the plurality of bits stored in the plurality of signature registers.

### BRIEF DESCRIPTION OF THE DRAWINGS

The invention may be understood by reference to the following description taken in conjunction with the accompanying drawings, in which like reference numerals identify like elements, and in which:

FIG. 1 shows a block diagram of a system, in accordance with one embodiment of the present invention;

FIGS. 2A-B show block diagrams illustrating an exemplary configuration of a frame buffer, a router, and a convolver that may be used in the graphics system shown in FIG. 1, in accordance with one embodiment of the present invention;

FIG. 3 shows a block diagram of a signature analyzer that may be used in the graphics system depicted in FIGS. 2A-B, in accordance with one embodiment of the present invention;

FIG. 4 shows a flow diagram illustrating a method that may be used for detecting faulty semiconductor devices in the graphics system depicted in FIGS. 2A-B; and

FIG. 5 shows a flow diagram illustrating a method of analyzing signatures that may be used by the signature analyzer shown in FIG. 3 to detect and isolate faulty semiconductor devices in the graphics system shown in FIG. 1, in accordance with one embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions may be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

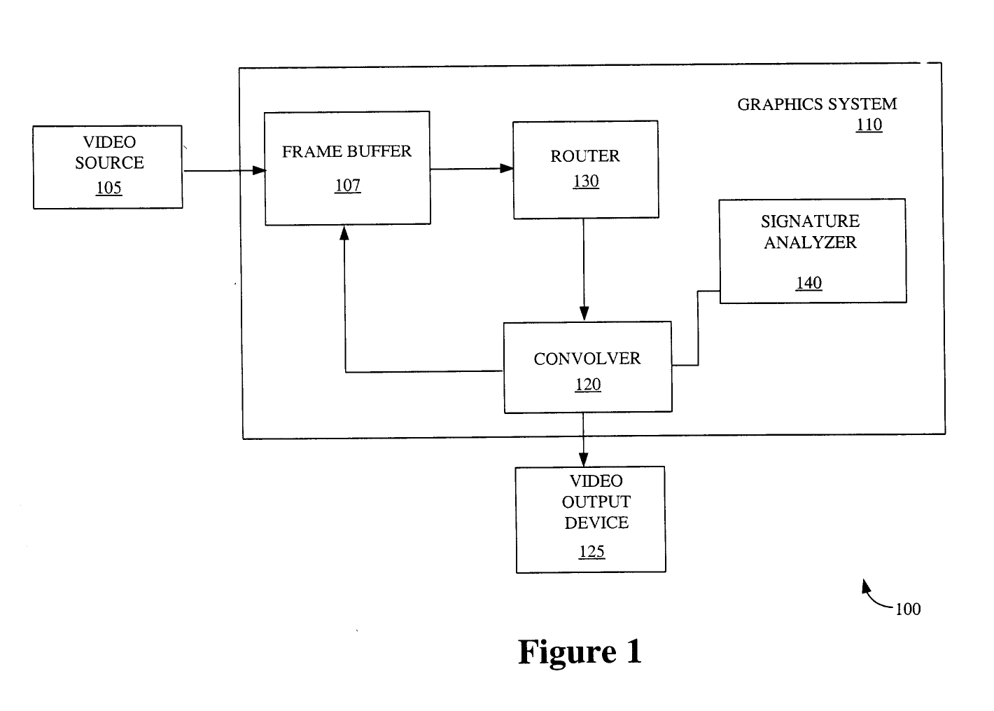

Referring now to FIG. 1, a block diagram showing a system 100 in accordance with one embodiment of the present invention is illustrated. The system 100 may include a video source 105 such as a digital video camera, a graphics rendering device, and the like. The video source 105 may, in one embodiment, provide a video data stream to a frame buffer 107 in a graphics system 110 such as a Sun Microsystems® video graphic system. The video data stream may comprise a plurality of frames (not shown) formed of a plurality of bits. In one embodiment, each one of the plurality of frames may be formed of approximately 50 million bits. In alternative embodiments, each frame may be formed of more or fewer bits. In one embodiment, the frame buffer 107 may store the video data from the one or more video streams.

A convolver 120 may be used by the graphics system 110 to process the data in the video data stream and provide a signal that may be used by a video output device 125 to produce an image. Although not so limited, the video output device 125 may include such devices as a television, a video projection device, a monitor, and the like. The convolver 120 may, in one embodiment, transmit requests to the frame buffer 107, which may provide data from the video data stream to a router 130 in response to the request. The router 130 may then direct the video data to the convolver 120.

The frame buffer 107, the convolver 120, the router 130, and other desirable elements of the graphics system 110 may include a plurality of semiconductor devices that may perform various functions. The semiconductor devices may be defective when installed, or they may fail during operation of the graphics system 110. Hereinafter, a semiconductor device that may be defective or may cause the graphics system 110 to operate in an incorrect or undesirable manner will be referred to as a “faulty semiconductor device.” Thus, in accordance with one embodiment of the present invention, the graphics system 110 may comprise a signature analyzer 140 that may be capable of detecting and isolating one or more faulty semiconductor devices.

The signature analyzer 140 may, in one embodiment, be coupled to the convolver 120. Signature data from a plurality of signature registers in the convolver 120 may be provided to the signature analyzer 140. In one embodiment, the signature data may be provided to the signature analyzer 140 in series using the Joint Test Action Group (JTAG) protocol, also known as the Institute of Electrical and Electronics Engineers (IEEE) Standard 1149.1, entitled “Standard test access port and boundary scan architecture.” As described in more detail below, the signature analyzer 140 may use the signature data from the convolver 120 to detect and isolate one or more faulty semiconductor devices in the frame buffer 107, the router 130, the convolver 120, and other components that it may be desirable to include in the system 100.

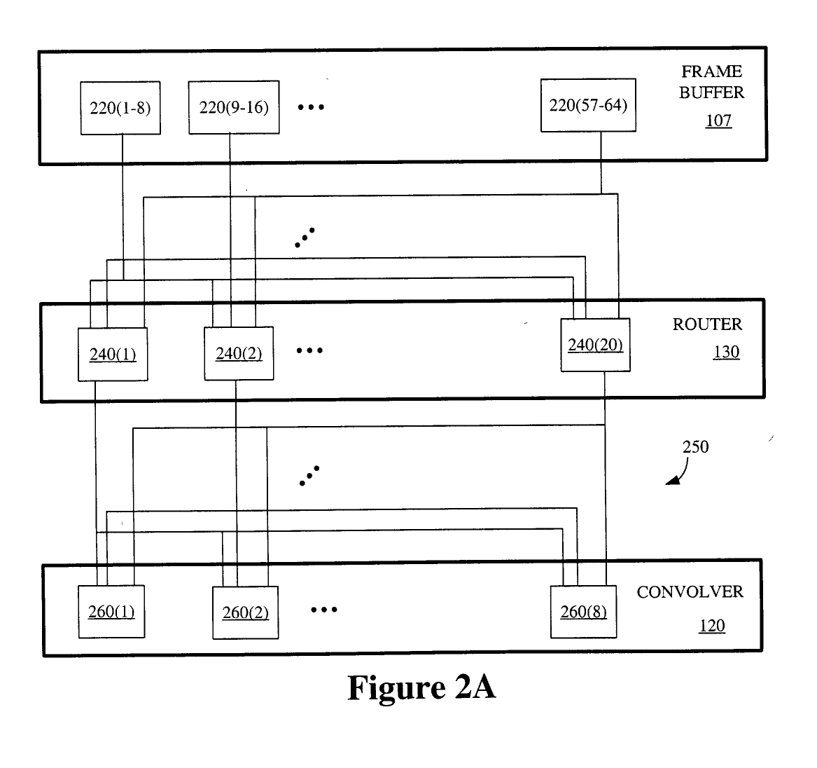

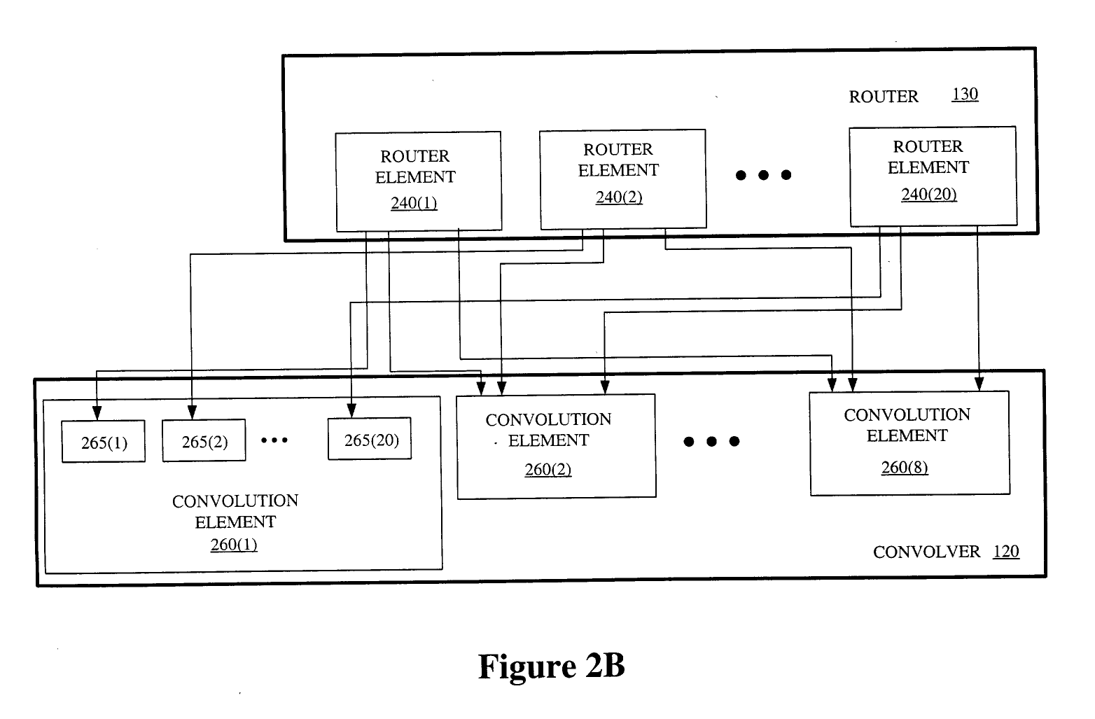

Referring now to FIG. 2A, a block diagram illustrating an exemplary arrangement of the frame buffer 107, the convolver 120, and the router 130 that may be used in the graphics system 10 is shown. The frame buffer 107 may include a plurality of frame buffer elements 220(1-64). In one embodiment, the frame buffer elements 220(1-64) may not include signature registers. In the interest of clarity, FIG. 2A shows one embodiment of the frame buffer 107 that includes 64 frame buffer elements 220(1-64). However, it should be appreciated that, in alternative embodiments, more or fewer frame buffer elements 220(1-64) may be deployed in the frame buffer 107 without deviating from the scope of the present invention. In one embodiment, each of the 64 frame buffer elements 220(1-64) may output 20 bits of video data. Thus, the frame buffer 107 may provide 1280 bits to the other components of the graphics system 110. It should, however, be appreciated that, in alternative embodiments, more or fewer bits may be output by the frame buffer elements 220(1-64) without deviating from the scope of the present invention.

The frame buffer elements 220(1-64) may be divided into one or more groups. In one embodiment, the 64 frame buffer elements 220(1-64) may be divided into 8 groups of 8 frame buffer elements 220(1-8), 220(9-16), . . . 220(57-64), as indicated in FIG. 2A. However, it should be appreciated that, in alternative embodiments, the frame buffer elements 220(1-64) may be divided into more or fewer groups having more or fewer frame buffer elements 220(1-64).

The frame buffer 107 may, in one embodiment, provide data to the router 130. The router 130 may, in one embodiment, include 20 router elements 240(1-20) capable of accessing 64 bits. Thus, the router 130 may provide 20×64=1280 bits to the frame buffer 107. However, it should be appreciated that, in alternative embodiments, more or fewer router elements 240(1-20) capable of accessing more or fewer than 64 bits may be used without deviating from the scope of the present invention. In one embodiment, the router elements 240(1-20) may not include signature registers.

The bits of video data may be provided to the various router elements 240(1-20) using any of a variety of methods and/or devices well known to those of ordinary skill in the art. In one embodiment, the bits may be divided such that each of the 20 router elements 240(1-20) receives a respective one of the 20 bits from each of the 64 corresponding frame buffer elements 220(1-64). For example, a first bit in the first frame buffer element 220(1) may be routed to the first router element 240(1) and a second bit in the first frame buffer element 220(1) may be routed to the second router element 240(2). For another example, a first bit in the second frame buffer element 220(2) may be routed to the first router element 240(1) and a second bit in the second frame buffer element 220(2) may be routed to the second router element 240(2). Thus, the first and second router elements 240(1-2) may each be provided with one bit from each of the frame buffer elements 220(1-64).

The router 130 may provide the bits of video data to the convolver 120 using a plurality of interconnects 250, which may, in alternative embodiments, be wires, traces, and the like. The convolver 120 may be capable of post-processing the video data stream provided by the video source 105 and sending the post-processed video data to other portions of the system 100 of which the graphics system 110 may be a part, such as the video output device 125 shown in FIG. 1. In accordance with one embodiment of the present invention, the convolver 120 may include a plurality of convolution elements 260(1-8) that may include a plurality of 8-bit input convolution signature registers 265(1-20), as shown in FIG. 2B. Thus, the convolver 120 may be capable of accessing 8×20×8=1280 bits from the router 130. It should, however, be appreciated that, in alternative embodiments, more or fewer convolution elements 260(1-8) including more or fewer input convolution signature registers 265(1-20) capable of analyzing more or fewer than 8 bits may be used without deviating from the scope of the present invention. In one embodiment, the input convolution signature registers 265(1-20) may be formed from linear hybrid cellular automata (LHCAs).

In one embodiment, the router 130 may provide the bits from each group of frame buffer elements 220(1-8), 220(9-16), 220(57-64) to each of the input convolution signature registers, e.g. the input convolution signature registers 265(1-20) in the convolution element 260(1) shown in FIG. 2B. For example, the router element 240(1) may provide the first bits from each of the first group of frame buffer elements 220(1-8) to the input convolution signature register 265(1) on the convolution element 260(1). Similarly, the router element 240(1) may provide the first bits from each of the second group of frame buffer elements 220(9-16) to the convolution element 260(2). For another example, the router element 240(2) may provide the second bits from each of the first group of frame buffer elements 220(1-8) to the input convolution signature register 265(2) on the convolution element 260(1). For yet another example, the router element 240(20) may provide the twentieth bits from each of the first group of frame buffer elements 220(1-8) to the input convolution signature register 265(20) on the convolution element 260(1). Thus, each convolution element 260(1-8) may, in one embodiment, access the video data from one group of the frame buffer elements 220(1-64).

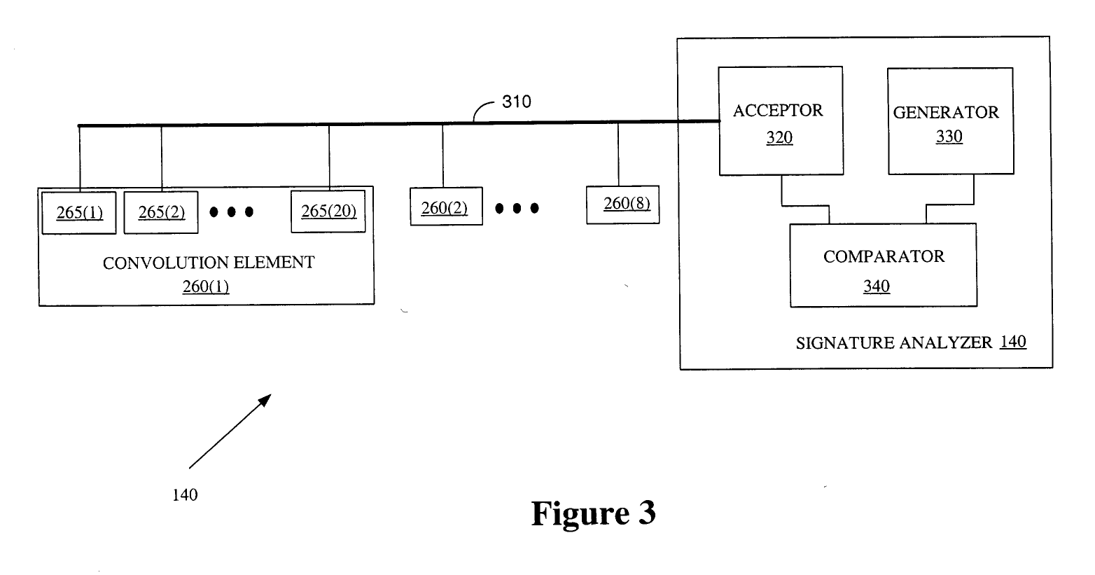

FIG. 3 shows a block diagram of the signature analyzer 140 that may be used in the graphics system 110. The signature analyzer 140 may, in one embodiment, be coupled to a serial bus 310, which may be coupled to the input convolution signature registers 265(1-20) on the convolution elements 260(1-8). In one embodiment, data from the input convolution signature registers 265(1-20) may be provided to the signature analyzer 140 in series via the serial bus 310 using the Joint Test Action Group (JTAG) protocol, also known as the Institute of Electrical and Electronics Engineers (IEEE) Standard 1149.1, entitled “Standard test access port and boundary scan architecture.” The JTAG Standard provides a serial bus standard that may be used to implement a general purpose hardware configuration, initialization, and status bus. However, it should be appreciated that, in alternative embodiments, an Inter-IC (12C) serial bus, a PCI bus, or any other standard or proprietary serial or parallel bus well known to those of ordinary skill in the art may be used in the graphics system 110.

The serial bus 310 may be coupled to an acceptor 320. In one embodiment, the bits in the input convolution signature registers 265(1-20) may be provided serially to the acceptor 320 via the serial bus 310, and the acceptor 320 may use the bits to form a plurality of signatures by any of a variety of methods well known to those of ordinary skill in the art. For example, the acceptor 320 may form a calculated signature from the bits in the input convolution signature register 265(1) by performing a binary addition of all the bits. For another example, the acceptor 320 may form a calculated signature from the bits in the input convolution signature register 265(1) by performing an exclusive-OR operation on adjacent bits. Hereinafter, the signatures that may be calculated by the acceptor 320 using the bits in the input convolution signature registers 265(1-20) are referred to as the “calculated signatures.”

The signatures that may be formed by the acceptor 320 using signature data from the input convolution signature registers 265(1-20) may depend upon the video data that may be provided to the frame buffer 107. Consequently, if a predetermined test pattern is provided to the frame buffer 107, the signatures that should be calculated during normal operation of the acceptor 320 may be determined in advance. Although not so limited, the test pattern may include such geometric shapes as triangles, squares, circles, or any other desirable shape or combinations thereof. Hereinafter, the signatures that may be calculated in advance using the predetermined test pattern are referred to as the “predetermined signatures.” In accordance with one embodiment of the present invention, a generator 330 may be provided to determine the predetermined signatures. Although not so limited, in one embodiment, the generator 330 may be one or more processors running one or more software applications.

The acceptor 320 may be coupled to a comparator 340 and may provide the calculated signatures to the comparator 340. Similarly, the generator 330 may provide the predetermined signatures to the comparator 340, which may compare the calculated signatures to the predetermined signatures. If the frame buffer 107, the router 130, the convolver 120, the interconnects 250, and any other components that it may be desirable to include in the graphics system 110 are operating correctly, the predetermined signatures may be substantially the same as the calculated signatures. However, if the predetermined signatures are not substantially the same as the calculated signatures, it may indicate that one or more components in the graphics system 110 may be faulty. By comparing the calculated and predetermined signatures, the comparator 340 may be capable of detecting and isolating one or more faulty semiconductor devices and/or one or more faulty interconnects 250 in the graphics system 110.

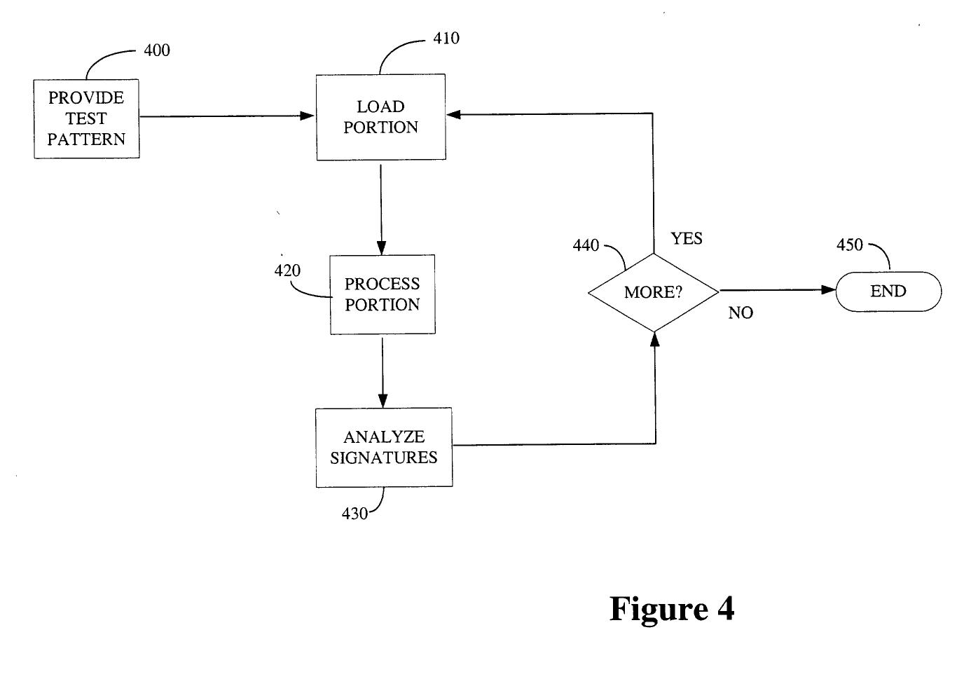

Referring now to FIG. 4, a flow diagram illustrating a method of detecting and isolating one or more faulty semiconductor devices and/or interconnects 250 in the graphics system 110 is shown. A test pattern may be provided (at 400) to the frame buffer 107 via a data stream. Although not so limited, the test pattern may include such geometric shapes as triangles, squares, circles, or any other desirable shape or combinations thereof. In response to a signal from the convolver 120, a portion of the test pattern may be loaded (at 410) into one or more groups of the frame buffer elements 220(1-64), which may provide the portion of the test pattern to the router 130 and the convolver 120. The convolver 120 may process (at 420) the portion of the test pattern and provide a signal to the one or more video output devices 125, which may display the test pattern.

In accordance with one embodiment of the present invention, and as described in more detail below, the signature analyzer 140 may analyze (at 430) signatures formed from the contents of the input convolution signature registers 265(1-20), and any other signature registers that it may be desirable to include in the graphics system 110. If it is determined (at 440) that portions of the test pattern may not have been analyzed, the convolver 120 may transmit a signal to the frame buffer 107 requesting more data. If not, the signature analysis may end (at 450).

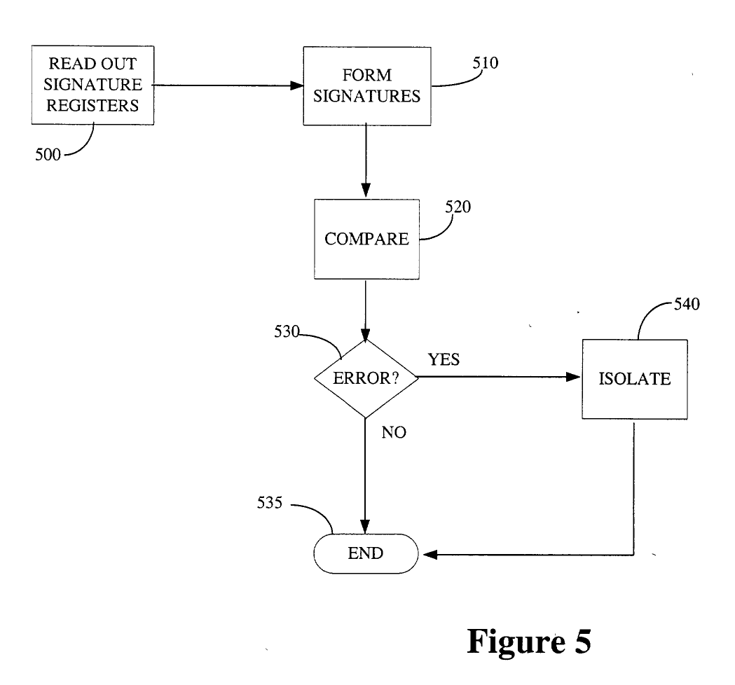

Referring now to FIG. 5, a flow diagram illustrating a method of analyzing signatures is shown. The signature analyzer 140 may read out (at 500) the contents of the input convolution signature registers 265(1-20), and any other signature registers that it may be desirable to include in the graphics system 110. Although not so limited, in one embodiment, the signature analyzer 140 may read out (at 500) the contents in series using the Joint Test Action Group (JTAG) protocol, also known as the Institute of Electrical and Electronics Engineers (IEEE) Standard 1149.1, entitled “Standard test access port and boundary scan architecture.”

The acceptor 320 may use the read-out contents to form (at 510) one or more calculated signatures by a variety of means well know to those of ordinary skill in the art. For example, the acceptor 320 may form a calculated signature from the bits in the input convolution signature register 265(1) by performing an exclusive-OR operation on adjacent bits. The generator 330 may use the test pattern to form (at 510) one or more predetermined signatures. In one embodiment, one calculated signature and one predetermined signature may be formed for each bit in each input convolution signature register 265(1-20) of each convolution element 260(1-8), for a total of 8×20×8=1280 calculated and predetermined signatures. However, it should be appreciated that, in alternative embodiments, more or fewer calculated and predetermined signatures may be formed without deviating from the scope of the present invention.

The comparator 340 may then compare (at 520) the calculated signature to the corresponding predetermined signature. If the comparator 340 determines (at 530) that all of the calculated signatures are substantially equal to the corresponding predetermined signatures, indicating that all the semiconductor devices and interconnects 250 in the graphics system 110 may be operating in a desirable manner, the signature analysis may end (at 535). However, if the comparator 340 determines (at 530) that one or more calculated signatures are not substantially equal to the corresponding predetermined signatures, indicating that one or more semiconductor devices and/or interconnects 250 in the graphics system 110 may be faulty, the signature analyzer 140 may isolate (at 540) the error using the calculated and predetermined signatures after which the signature analysis may end (at 535).

Although not so limited, the following examples illustrate how the comparator 340 may isolate a faulty semiconductor device in the graphics system 110, in accordance with one embodiment of the present invention. For a first illustrative example, if the comparator 340 determines that all of the calculated signatures formed using the first bits of each of the 8-bit input convolution signature registers 265(1-20) in the convolution element 260(1) are not substantially equal to the corresponding predetermined signatures, the comparator 340 may determine that the frame buffer element 220(1) may be faulty. For a second illustrative example, if the comparator 340 determines that all of the calculated signatures formed using the eight bits of the first input convolution signature registers (e.g. the input convolution signature register 265(1) in the convolution element 260(1)) in all of the convolution elements 260(1-8) are not substantially equal to the corresponding predetermined signatures, the comparator 340 may determine that the router element 240(1) may be faulty. For a third illustrative example, if the comparator 340 determines that all of the calculated signatures formed using the bits in the input convolution signature registers 265(1-20) in the convolution element 260(1) are not substantially equal to the corresponding predetermined signatures, the comparator 340 may determine that the convolution element 260(1) may be faulty.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope of the invention. Accordingly, the protection sought herein is as set forth in the claims below.

What is claimed:

1. An apparatus, comprising:
a buffer adapted to receive a data stream;
a convolver comprising at least one signature register, wherein the signature register is adapted to store a plurality of bits;
a router adapted to route the data stream from the buffer to the convolver; and
an analyzer adapted to access the signature registers, wherein the analyzer is capable of isolating at least one of a faulty semiconductor device and a faulty interconnect using the plurality of bits stored in the signature register.

2. The apparatus of claim 1, wherein the buffer comprises a plurality of buffer semiconductor devices, wherein each buffer semiconductor device is adapted to store at least one bit from the data stream.

3. The apparatus of claim 2, wherein the plurality of buffer semiconductor devices are divided into a plurality of groups, wherein the buffer semiconductor devices in each group are adapted to store at least one bit from the data stream.

4. The apparatus of claim 3, wherein the convolver comprises at least one convolution element including at least one signature register.

5. The apparatus of claim 4, wherein the signature register is adapted to access the buffer semiconductor device corresponding to the selected group.

6. The apparatus of claim 1, further comprising a video source adapted to provide a test pattern to the buffer via the data stream.

7. The apparatus of claim 6, wherein the analyzer comprises at least one generator adapted to form a plurality of predetermined signatures using the test pattern.

8. The apparatus of claim 7, wherein the analyzer comprises at least one acceptor adapted to form a plurality of calculated signatures using the plurality of bits stored in the signature register.

9. The method of claim 8, wherein the acceptor is adapted to form the plurality of calculated signatures using a logical exclusive-OR operation applied to the plurality of bits stored in the signature register.

10. The method of claim 8, wherein the acceptor is adapted to form the plurality of calculated signatures by summing the plurality of bits stored in the signature register.

11. The apparatus of claim 8, wherein the analyzer comprises a comparator adapted to isolate at least one faulty semiconductor device by determining if the plurality of calculated signatures are each substantially equal to a corresponding one of the plurality of predetermined signatures.

12. The apparatus of claim 1, wherein the faulty semiconductor device is in at least one of the buffer, the convolver, and the router.

13. The apparatus of claim 1, wherein the interconnect is at least one of a wire and a trace.

14. A method comprising:
providing a test pattern to a buffer via a data stream, wherein the buffer is coupled to a router and a convolver;
accessing at least one signature register in the convolver, wherein the signature register is adapted to store a plurality of bits; and
detecting at least one of a faulty semiconductor device and a faulty interconnect using the plurality of bits stored in the plurality of signature registers.

15. The method of claim 14, wherein accessing the signature register comprises reading out the plurality of bits stored in the signature register in series.

16. The method of claim 15, wherein forming a plurality of calculated signatures using the read-out bits comprises applying a logical exclusive-OR operation to the read-out bits.

17. The method of claim 14, wherein at least one of the faulty semiconductor device and the faulty interconnect comprises forming a plurality of calculated signatures using the read-out bits.

18. The method of claim 17, wherein detecting the at least one of the faulty semiconductor device and the faulty interconnect comprises forming a plurality of predetermined signatures using the test pattern, wherein each predetermined signature corresponds to one of the plurality of calculated signatures.

19. The method of claim 18, wherein detecting the at least one of the faulty semiconductor device and the faulty interconnect comprises determining if each of the plurality of calculated signatures is substantially equal to the corresponding predetermined signature.

20. The method of claim 19, wherein detecting the at least one of the faulty semiconductor device and the faulty interconnect comprises isolating the at least one of the faulty semiconductor device and the faulty interconnect using the plurality of calculated and predetermined signatures.

21. The method of claim, wherein detecting the faulty semiconductor device comprises detecting the at least one of the faulty semiconductor device in at least one of the buffer, the router, and the convolver.

21. A system, comprising:
a video source adapted to provide a test pattern to a buffer via a data stream;
a convolver adapted to process the data stream, wherein the convolver includes at least one signature register;
a router adapted to route the data stream from the buffer to the convolver;
an acceptor adapted to form a plurality of signatures using a plurality of bits stored in the signature register;
a generator adapted to generate a plurality of predetermined signatures using the test pattern, wherein each of the predetermined signatures corresponds to one of the calculated signatures; and
a comparator adapted to isolate at least one of a faulty semiconductor device and a faulty interconnect using the plurality of calculated signatures and the corresponding predetermined signatures.

21. The system of claim 20, wherein the signature register is a linear hybrid cellular automaton.

22. The system of claim 20, wherein the acceptor is adapted to form a plurality of signatures by applying a logical exclusive-OR operation to the plurality of bits stored in the signature register.

23. The system of claim 20, wherein the generator comprises a processor.

24. The system of claim 23, wherein the processor is adapted to run software to generate the plurality of predetermined signatures.

25. The system of claim 20, wherein the acceptor is adapted to access the signature registers via a bus.

26. The system of claim 25, wherein the bus conforms to the JTAG standard.

27. The system of claim 25, wherein the bus is an Inter-IC (12C) serial bus.

28. The system of claim 25, wherein the bus is a PCI bus.

29. The system of claim 20, wherein the video source is a camera.

30. The system of claim 20, wherein the video source is a graphics rendering device.

31. The system of claim 20, wherein the faulty semiconductor device is in at least one of the buffer, the router, and the convolver.

32. A device, comprising:
means for providing a data stream to a buffer;
means for accessing a plurality of bits in at least one signature register on a convolver, wherein the convolver is adapted to access the data stream via a router coupled to the buffer; and
means for detecting at least one of a faulty semiconductor device and a faulty interconnect by forming a plurality of signatures using the plurality of bits in the signature register.
